(19) United States
(12) Patent Application Publication
(10) Pub. No.: US 2017/0303394 A1
(43) Pub. Date: Oct. 19, 2017

(54) PRINTED WIRING BOARD AND METHOD FOR MANUFACTURING THE SAME

(71) Applicant: IBIDEN CO., LTD., Ogaki (JP)

(72) Inventors: Hiroyuki NISHIOKA, Ogaki (JP); Katsuya Takagi, Ogaki (JP); Hiroaki Uno, Ogaki (JP); Satoru Katada, Ogaki (JP)

(73) Assignee: IBIDEN CO., LTD., Ogaki (JP)

(21) Appl. No.: 15/487,652

(22) Filed: Apr. 14, 2017

(30) Foreign Application Priority Data
Apr. 14, 2016 (JP) 2016-081460

(51) Int. Cl. H05K 1/09; B32B 37/14; H05K 3/46; B32B 7/02; B32B 15/20; H05K 1/03

(52) U.S. Cl. CPC H05K 1/09; B32B 15/20; H05K 1/032; H05K 3/4644; B32B 7/02; B32B 37/14; B32B 2457/08; B32B 2309/105

(57) ABSTRACT

A printed wiring board includes a laminated base material including a surface conductor layer, a conductor layer, an interlayer insulating layer interposed between the surface conductor layer and the conductor layer, and an internal bonding layer interposed between the interlayer insulating layer and the surface conductor layer and/or conductor layer, and a solder resist layer laminated on a surface of the laminated base material such that the solder resist layer is covering the surface conductor layer. The internal bonding layer has a surface in contact with the interlayer insulating layer such that the surface of the internal bonding layer has arithmetic average roughness Ra in a range of 100 nm or more and 300 nm or less, and the surface conductor layer has a surface on a solder resist layer side such that the surface of the surface conductor layer has arithmetic average roughness Ra of less than 100 nm.

### CROSS-REFERENCE TO RELATED APPLICATIONS

The present application is based upon and claims the benefit of priority to Japanese Patent Application No. 2016-081460, filed Apr. 14, 2016, the entire contents of which are incorporated herein by reference.

### BACKGROUND OF THE INVENTION

### Field of the Invention

The present invention relates to a printed wiring board and a method for manufacturing the printed wiring board.

### Description of Background Art

Japanese Patent Laid-Open Publication No. HEI 10-150250 describes that, in a printed wiring board in which a solder resist layer is provided on a surface of a wiring substrate in which a conductor circuit is formed, a surface of the conductor circuit is formed as a roughened layer. The entire contents of this publication are incorporated herein by reference.

### SUMMARY OF THE INVENTION

According to one aspect of the present invention, a printed wiring board includes a laminated base material including a surface conductor layer, a conductor layer, an interlayer insulating layer interposed between the surface conductor layer and the conductor layer, and an internal bonding layer interposed between the interlayer insulating layer and the surface conductor layer and/or conductor layer, and a solder resist layer laminated on a surface of the laminated base material such that the solder resist layer is covering the surface conductor layer. The internal bonding layer has a surface in contact with the interlayer insulating layer such that the surface of the internal bonding layer has an arithmetic average roughness Ra in a range of 100 nm or more and 300 nm or less, and the surface conductor layer has a surface on a solder resist layer side such that the surface of the surface conductor layer has an arithmetic average roughness Ra of less than 100 nm.

According to another aspect of the present invention, a method for manufacturing a printed wiring board includes forming a laminated base material including a surface conductor layer, a conductor layer, an interlayer insulating layer interposed between the surface conductor layer and the conductor layer, and an internal bonding layer interposed between the interlayer insulating layer and the surface conductor layer and/or conductor layer, and laminating a solder resist layer on a surface of the laminated base material such that the solder resist layer covers the surface conductor layer. The forming of the laminated base material includes forming the internal bonding layer on a surface of the conductor layer having an arithmetic average roughness Ra of less than 100 nm such that the internal bonding layer has an outer surface having an arithmetic average roughness Ra in a range of 100 nm or more and 300 nm or less, and forming the interlayer insulating layer on the conductor layer on which the internal bonding layer is formed, and forming the surface conductor layer on the interlayer insulating layer, and the laminating of the solder resist layer includes laminating the solder resist layer on a surface of the surface conductor layer having an arithmetic average roughness Ra of less than 100 nm.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a schematic cross-sectional view of a printed wiring board (1A) according to an embodiment of the present invention;

FIG. 2A is a schematic cross-sectional view (1) for describing a manufacturing process of the printed wiring board (1A) according to the embodiment of the present invention;

FIG. 2B is a schematic cross-sectional view (2) for describing a manufacturing process of the printed wiring board (1A) according to the embodiment of the present invention;

FIG. 2C is a schematic cross-sectional view (3) for describing a manufacturing process of the printed wiring board (1A) according to the embodiment of the present invention;

FIG. 2D is a schematic cross-sectional view (4) for describing a manufacturing process of the printed wiring board (1A) according to the embodiment of the present invention;

FIG. 2E is a schematic cross-sectional view (5) for describing a manufacturing process of the printed wiring board (1A) according to the embodiment of the present invention;

FIG. 2F is a schematic cross-sectional view (6) for describing a manufacturing process of the printed wiring board (1A) according to the embodiment of the present invention;

FIG. 2G is a schematic cross-sectional view (7) for describing a manufacturing process of the printed wiring board (1A) according to the embodiment of the present invention;

FIG. 2H is a schematic cross-sectional view (8) for describing a manufacturing process of the printed wiring board (1A) according to the embodiment of the present invention;

FIG. 2I is a schematic cross-sectional view (9) for describing a manufacturing process of the printed wiring board (1A) according to the embodiment of the present invention;

FIG. 2J is a schematic cross-sectional view (10) for describing a manufacturing process of the printed wiring board (1A) according to the embodiment of the present invention;

FIG. 2K is a schematic cross-sectional view (11) for describing a manufacturing process of the printed wiring board (1A) according to the embodiment of the present invention;

FIG. 2L is a schematic cross-sectional view (12) for describing a manufacturing process of the printed wiring board (1A) according to the embodiment of the present invention;

FIG. 2M is a schematic cross-sectional view (13) for describing a manufacturing process of the printed wiring board (1A) according to the embodiment of the present invention;

FIG. 3 is an enlarged view of a region indicated by X in the schematic cross-sectional view illustrated in FIG. 1;

FIG. 4 is a schematic cross-sectional view of a printed wiring board (1B) (of a coreless structure) according to an embodiment of the present invention (an enlarged view of a region indicated by X in the schematic cross-sectional view of the printed wiring board (1B) according to the embodiment of the present invention is the same as the one illustrated in FIG. 3);

FIG. 5A is a schematic cross-sectional view (1) for describing a manufacturing process of the printed wiring board (1B) according to the embodiment of the present invention;

FIG. 5B is a schematic cross-sectional view (2) for describing a manufacturing process of the printed wiring board (1B) according to the embodiment of the present invention;

FIG. 5C is a schematic cross-sectional view (3) for describing a manufacturing process of the printed wiring board (1B) according to the embodiment of the present invention;

FIG. 6 is a picture of a TEM (transmission electron microscope) observation image near a surface bonding layer 50 of an actually prepared printed wiring board (1A) according to the embodiment of the present invention; and

FIG. 7 illustrates XPS analysis results of elements at points indicated in FIG. 6.

### DETAILED DESCRIPTION OF THE EMBODIMENTS

The embodiments will now be described with reference to the accompanying drawings, wherein like reference numerals designate corresponding or identical elements throughout the various drawings.

### Printed Wiring Board

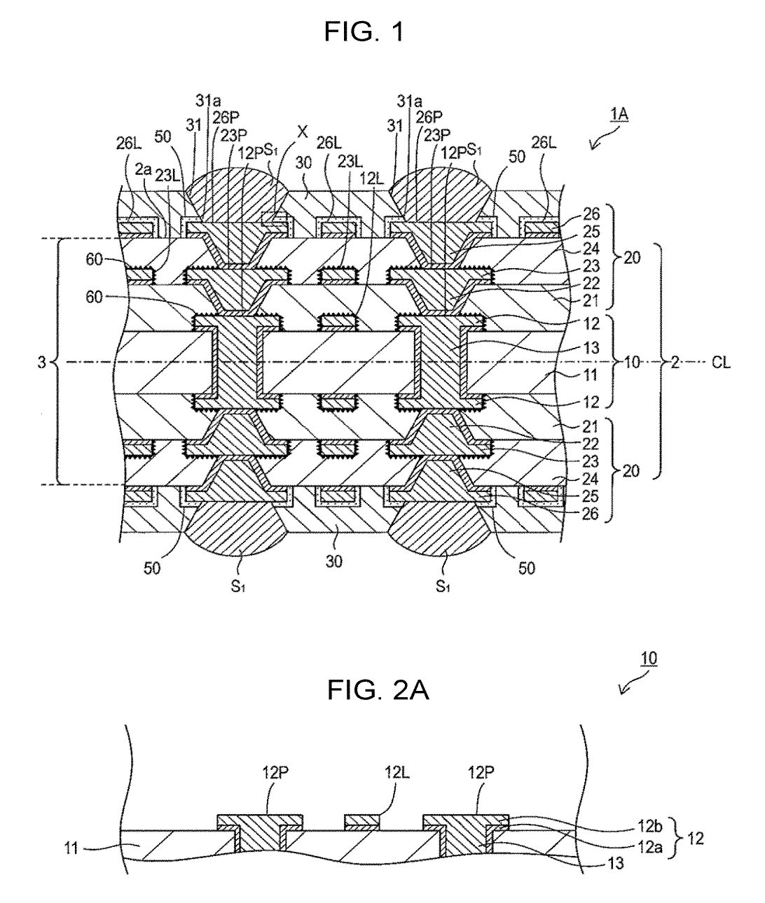

A printed wiring board (1A) according to an embodiment of the present invention is structured as illustrated in the schematic cross-sectional view of FIG. 1.

The printed wiring board (1A) includes one or more laminated conductor layers and one or more laminated insulating layers. Specifically, the printed wiring board (1A) includes a core layer 10, build-up layers 20, and solder resist layers 30. The printed wiring board (1A) is a package substrate, on which a semiconductor element such as an IC chip can be mounted by flip chip connection, and can be mounted on another printed wiring board such as a motherboard after the semiconductor element is mounted. The printed wiring board (1A) of the present embodiment is a multilayer laminated printed wiring board, and as a whole has a plate-like or film-like shape.

The printed wiring board (1A) according to the present embodiment has a structure that is vertically symmetrical about a central axis (CL) of a core insulating layer 11. Therefore, in the following description, only one side of the central axis (CL) is described. In the present embodiment, the printed wiring board (1A) has the structure that is vertically symmetrical about the central axis (CL). However, in accordance with a structure of an intended circuit, the printed wiring board (1A) may also have an asymmetric structure. The structure of the printed wiring board (1A) is not limited.

The core layer 10 includes the core insulating layer 11, and first conductor layers 12 that are respectively formed on two main surfaces of the core insulating layer 11. Further, filled through holes 13 that electrically connect between the first conductor layers 12 that are respectively formed on the two main surfaces of the core insulating layer 11 are provided in the core layer 10.

The first conductor layers 12 are each a pattern that includes first conductor pads (12P) and first conductor wirings (12L).

The build-up layers 20 are respectively laminated on both sides of the core layer 10. The build-up layers 20 are each formed by alternately laminating conductor layers and insulating layers and, specifically, each have, for example, the following structure.

A first insulating layer 21 covers the first conductor layer 12 of the core layer 10. A second conductor layer 23 is formed on a surface of the first insulating layer 21 on a side where the first conductor layer 12 is not formed. First conductor vias 22 that penetrate the first insulating layer 21 and electrically connect the first conductor layer 12 and the second conductor layer 23 are formed in the first insulating layer 21. The second conductor layer 23 is a pattern that includes second conductor pads (23P) and second conductor wirings (23L). The second conductor layer 23 is further covered by a second insulating layer 24.

A surface conductor layer (third conductor layer) 26 is formed on a surface of the second insulating layer 24 on a side where the second conductor layer 23 is not formed. The surface conductor layer (third conductor layer) 26 is a pattern that includes surface conductor pads (third conductor pads) (26P) and surface conductor wirings (third conductor wirings) (26L). Second conductor vias 25 that penetrate the second insulating layer 24 and electrically connect the second conductor layer 23 and the surface conductor layer 26 are formed in the second insulating layer 24.

The surface conductor layer 26 is a conductor layer positioned as an outermost layer among the conductor layers and includes at least multiple third conductor pads (26P) that are connected to substrate mounting parts (not illustrated in the drawings), and, as illustrated in the drawings, may further include other third conductor wirings (26L). The build-up layer 20 may include more insulating layers and/or conductor layers, and the conductor layers may be connected via more conductor vias.

The solder resist layer 30 is an outermost layer of the printed wiring board (1A) and is provided so as to cover the surface conductor layer 26 of the build-up layer 20. The solder resist layer 30 is an insulating layer that is positioned as an outermost layer among the insulating layers included in the printed wiring board (1A). Multiple openings 31 are provided in the solder resist layer 30. The third conductor pads (26P) of the surface conductor layer 26 are positioned so as to be respectively exposed in the openings 31.

The third conductor pads (26P) are respectively formed so as to extend into edges of the openings 31 (specifically, laminated base material vicinity portions (31a) of the openings 31). The third conductor pads (26P) formed in this way are referred to as SMD (Solder Mask Defined) pads. On the other hand, although not illustrated in the drawings, in an opening, a conductor pad that is formed such that a gap is formed between the conductor pad and an edge of the opening (specifically, a laminated base material vicinity portion of the opening) is referred to as an NSMD (Non Solder Mask Defined) pad. In the present specification, when it is necessary to distinguish between an SMD pad and an NSMD pad, the third conductor pads (26P) and the openings 31 are respectively referred to as SMD pads (26P) and SMD openings 31.

Solder bumps (S₁) are respectively provided on the third conductor pads (26P) in the openings 31.

A portion of the printed wiring board (1A) excluding the solder resist layers 30, that is, a portion including the core layer 10 and the build-up layers 20 that are respectively formed on both sides of the core layer 10, is referred to as a laminated base material 2. Further, a portion of the laminated base material 2 excluding the surface conductor layers 26, which are the outermost layers, is referred to as a laminate main body 3. Among the insulating layers included in the printed wiring board (1A), the insulating layers (the first insulating layer 21 and the second insulating layer 24) included in the laminated base material 2 may each be referred to as an “interlayer insulating layer”, and the solder resist layer 30 may be referred to as a “protective insulating layer”. The first insulating layer 21, which is an interlayer insulating layer, is sandwiched by the first conductor layer 12 and the second conductor layer 23. The second insulating layer 24 is sandwiched by the second conductor layer 23 and the surface conductor layer (third conductor layer) 26.

The interlayer insulating layers can each be formed of an insulating resin composition such as a thermosetting resin composition or a photosensitive resin composition.

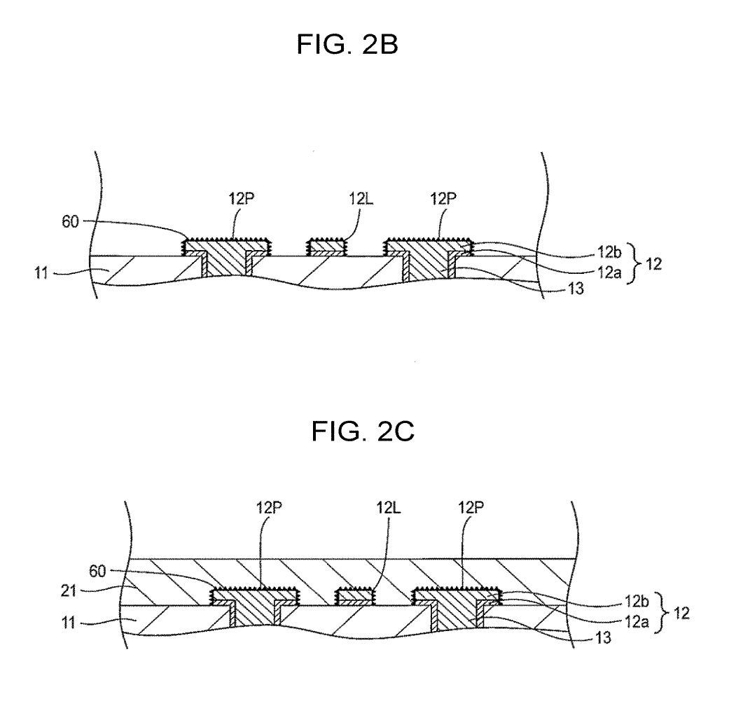

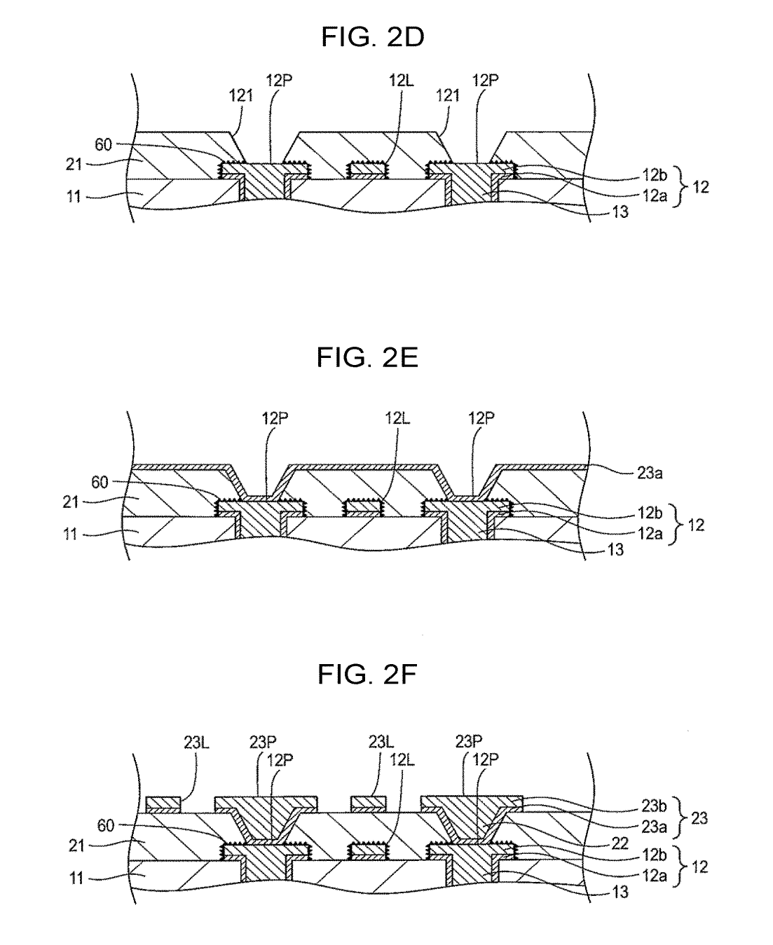

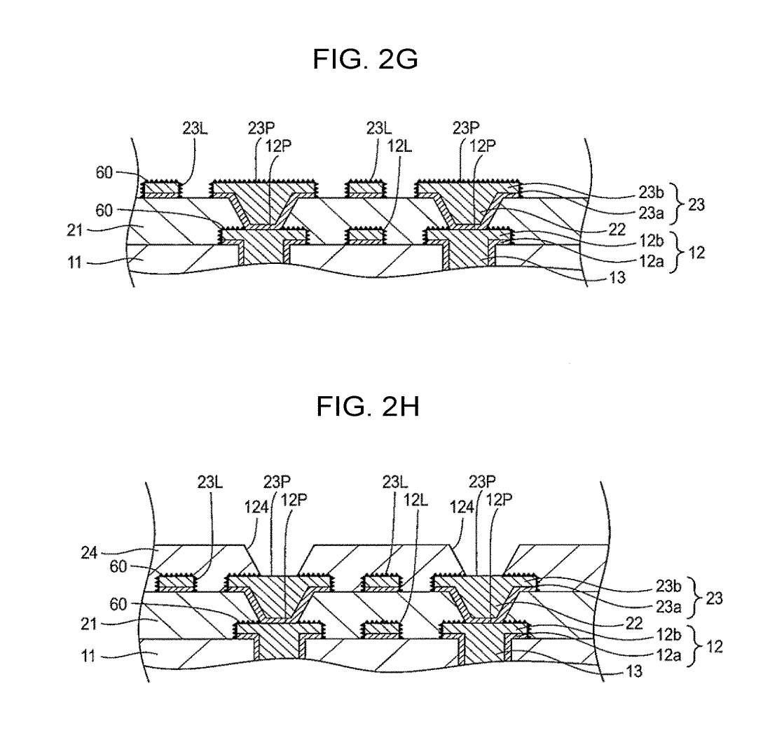

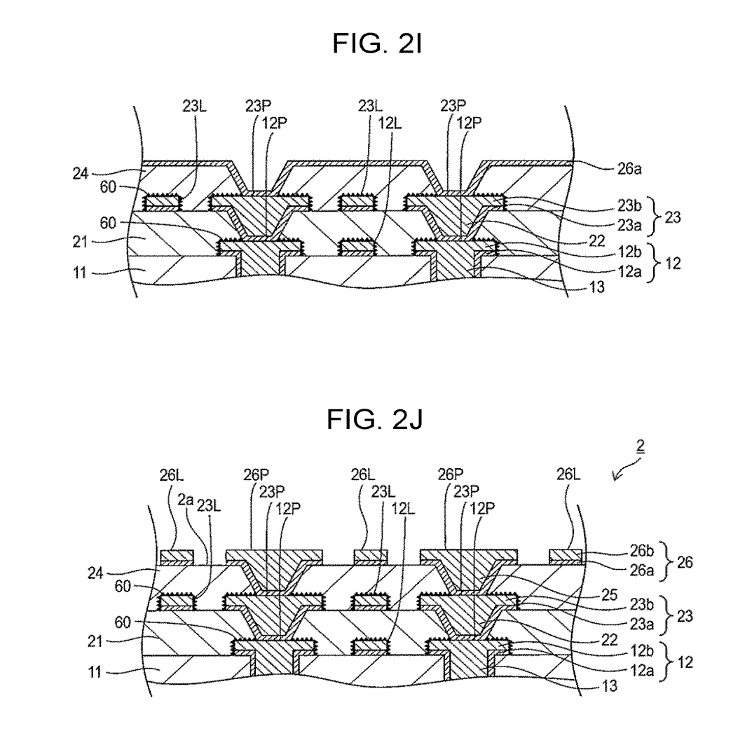

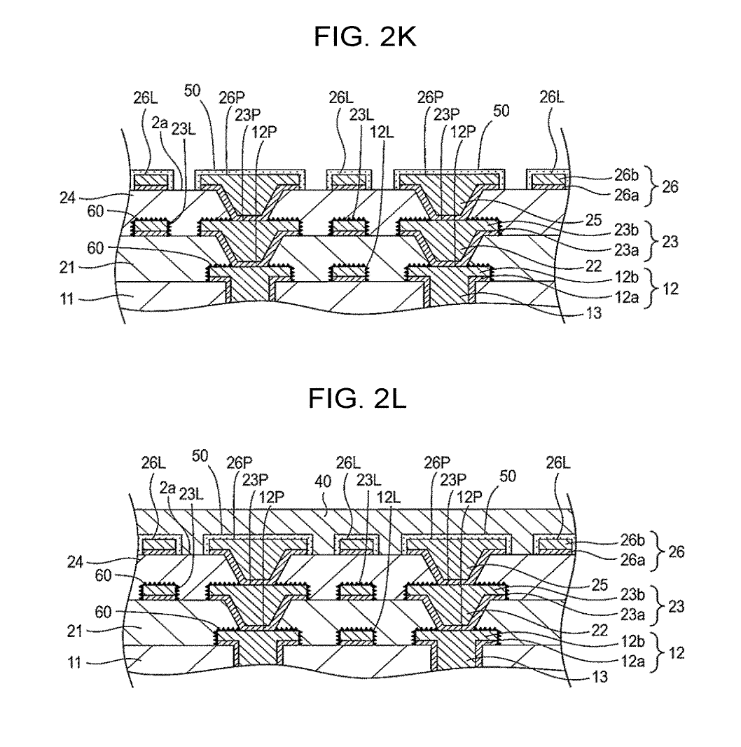

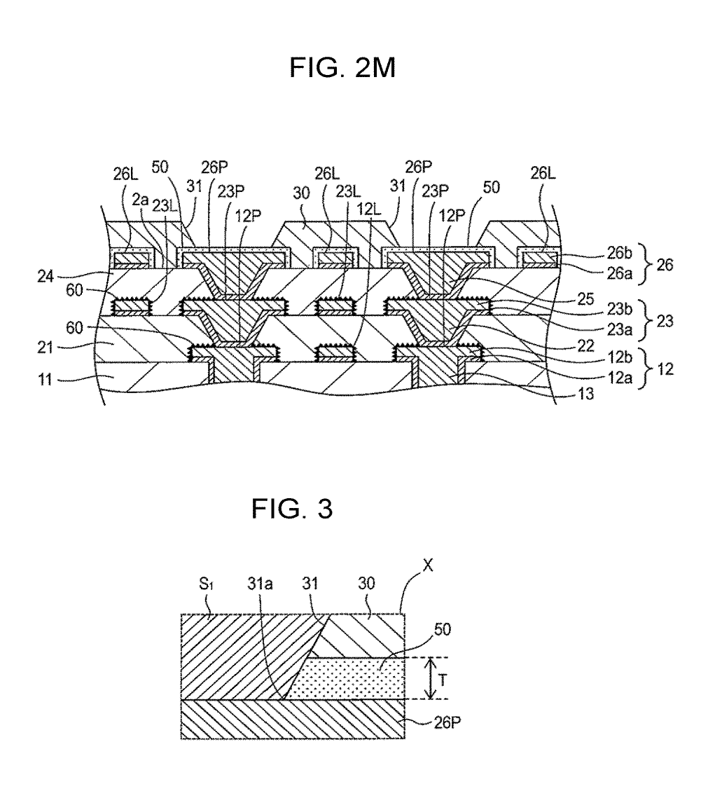

The conductor layers (the first conductor layer 12, the second conductor layer 23, the surface conductor layer 26, the filled through holes 13, the first conductor vias 22, and the second conductor vias 25), as illustrated in FIG. 1, may each be formed by laminating multiple conductor layers. For example, as indicated by reference numeral symbols in FIG. 2A-2M, the first conductor layer 12 can be formed by a laminated structure that includes a first seed layer (12a) and a first electrolytic plating layer (12b); the second conductor layer 23 can be formed by a laminated structure that includes a second seed layer (23a) and a second electrolytic plating layer (23b); and the surface conductor layer (third conductor layer) 26 can be formed of a third seed layer (26a) and a third electrolytic plating layer (26b). Further, a seed layer of each of the filled through holes 13 can be integrally formed with the first seed layer (12a). Similarly, a seed layer of each of the first conductor vias 22 can be integrally formed with the second seed layer (23a); and a seed layer of the second conductor vias 25 can be integrally formed with the third seed layer (26a). The seed layers are each a base layer for forming an electrolytic plating layer on a surface of each of the interlayer insulating layers (21, 24) and the core insulating layer 11, and specifically, are each an electroless plating layer, a metal layer formed by sputtering, or the like. As a conductor that forms the conductor layers, for example, copper can be used. In particular, the third electrolytic plating layer (26b) of the surface conductor layer (third conductor layer) 26 is preferably a layer of electrolytically plated copper.

The solder resist layer 30 is a layer composed of an insulating resin composition. A composition of the insulating resin composition that forms the solder resist layer 30 is not particularly limited.

Further, solder bumps (S₁) are respectively provided on the third conductor pads (26P) surrounded by the openings 31. In this case, before the solder bumps (S₁) are provided, a surface treatment layer (not illustrated in the drawings) for preventing oxidation may be provided on a surface of each of the third conductor pads (26P). By providing the surface treatment layer on the surface of each of the third conductor pads (26P), oxidation of the third conductor pads (26P) before the formation of the solder bumps can be prevented and adhesion of solder to the third conductor pads (26P) can be improved. Examples of the surface treatment layer include plating films such as a nickel-gold plating film, a nickel-palladium-gold plating film and a tin plating film, and an OSP (organic solderability preservative) film (preflux film), and the like.

In the printed wiring board (1A) of the present embodiment, an internal bonding layer 60 is interposed between the first insulating layer 21, which is an interlayer insulating layer, and at least the first conductor layer 12 among the first conductor layer 12 and the second conductor layer 23, which are a pair of conductor layers that are formed so as to sandwich the first insulating layer 21. Further, similarly, an internal bonding layer 60 is interposed between the second insulating layer 24, which is an interlayer insulating layer, and at least the second conductor layer 23 among the second conductor layer 23 and the surface conductor layer 26, which are a pair of conductor layers that are formed so as to sandwich the second insulating layer 24. Further, a surface bonding layer 50 is interposed between the surface conductor layer 26, which includes the third electrolytic plating layer (26b), and the solder resist layer 30.

Therefore, characteristics of the first conductor layer 12 and second conductor layer 23 (which are conductor layers other than the surface conductor layer 26 and hereinafter may be referred to as “internal conductor layers”), the surface conductor layer 26, the interlayer insulating layers (the first insulating layer 21 and the second insulating layer 24), the solder resist layer 30, the internal bonding layers 60, and the surface bonding layer 50 in the printed wiring board (1A) of the present embodiment are respectively described.

### Internal Conductor Layers

The first conductor layer 12 and the second conductor layer 23, which are internal conductor layers, are preferably conductor layers containing copper, and more preferably, as illustrated in the drawings, are layers that respectively include the first electrolytic plating layer (12b) and the second electrolytic plating layer (23b) that are each composed of electrolytically plated copper.

Surfaces of the first conductor layer 12 and the second conductor layer 23, preferably, at least surfaces of the first electrolytic plating layer (12b) and the second electrolytic plating layer (23b), on which the internal bonding layers 60 are to be formed, more preferably, the entire surfaces of the first conductor layer 12 and the second conductor layer 23, have an arithmetic average roughness (Ra) of preferably less than 100 nm in a state before the internal bonding layers 60 are formed. In the present specification, the arithmetic average roughness (Ra) means an arithmetic average roughness (Ra) defined by JIS. In the present embodiment, in the state before the internal bonding layers 60 are formed, by using the first conductor layer 12 and the second conductor layer 23, of which the surfaces have small Ra values, even when current densities near the surfaces of the conductor layers become high due to a skin effect, resistances of the conductor layers can be kept relatively low and thus, electrical loss can be reduce, which is advantageous.

### Surface Conductor Layer

The surface conductor layer 26 is preferably a conductor layer containing copper, and more preferably, as illustrated in the drawings, is a layer that includes the third electrolytic plating layer (26b) composed of electrolytically plated copper.

A surface of the surface conductor layer 26, preferably, at least a surface of the third electrolytic plating layer (26b), on which the solder resist layer 30 is laminated, more preferably, the entire surface of the surface conductor layer 26, has an arithmetic average roughness (Ra) of less than 100 nm. In the present embodiment, by using the surface conductor layer 26, of which the surface has a small Ra value, even when a current density near the surface of the conductor layer becomes high due to a skin effect, resistance of the surface conductor layer 26 can be kept relatively low and thus, electrical loss can be reduce, which is advantageous. Further, as will be described later, in a preferred embodiment in which the solder resist layer 30 is formed by laminating and photocuring a photosensitive resin composition on a surface of the laminated base material 2 including the surface conductor layer 26, when the Ra value of the surface conductor layer 26 is in the above-described range, irradiation light for photocuring can be reflected by the surface of the surface conductor layer 26 and thus a good photocuring efficiency is expected.

### Interlayer Insulating Layers

As described above, the interlayer insulating layers (21, 24) are insulating layers that are each formed by curing an insulating resin composition such as a thermosetting resin composition or a photosensitive resin composition, and are preferably insulating layers that are each formed by curing a thermosetting resin composition. These insulating resin compositions preferably each contain inorganic filler as a reinforcing material, and the content of the inorganic filler is, for example, 30-80 mass %.

The thermosetting resin composition may be a composition that contains at least a thermosetting resin. Specific examples of the thermosetting resin include an epoxy resin, a phenol resin and the like. It is also possible that two or more thermosetting resins are used in combination. As the thermosetting resin, an epoxy resin is particularly preferable.

Examples of the epoxy resin include a bisphenol A type epoxy resin, a bisphenol F type epoxy resin, a novolac type epoxy resins such as a phenol novolac type epoxy resin or an alkylphenol novolac type epoxy resin (such as a cresol novolak type epoxy resin), an alicyclic epoxy resin, a biphenyl type epoxy resin, a naphthalene type epoxy resin, a dicyclopentadiene type epoxy resin, an epoxy compound of a condensate of a phenol and an aromatic aldehyde having a phenolic hydroxyl group, triglydisyl isocyanurate, and the like. It is also possible that two or more epoxy resins are used in combination. The interlayer insulating layers (21, 24) preferably each have a low dielectric constant in order to reduce a capacitance between conductor layers.

In order for the interlayer insulating layers (21, 24) to each have a low dielectric constant, the resin contained in the insulating resin composition is preferably a resin having few polar groups. An example of a resin having few polar groups is a resin that does not have an acryloyl group or a methacryloyl group or a functional group derived from an acryloyl group or a methacryloyl group. As a resin that does not have an acryloyl group or a methacryloyl group or a functional group derived from an acryloyl group or a methacryloyl group, in particular, an epoxy resin or a phenol resin as described above is preferable and an epoxy resin is particularly preferable.

It is possible that the thermosetting resin composition for forming the interlayer insulating layers (21, 24) is impregnated into a core material composed of fibers such as glass fibers or does not contain a core material. However, a thermosetting resin composition that does not contain a core material is particularly preferable.

As the thermosetting resin composition, it is preferable to use a separately prepared thermosetting resin film. For example, as a thermosetting resin film, a commercially available insulating film for a build-up substrate can be used.

The thermosetting resin composition may be used in a form of a fluid (liquid or paste) containing a suitable solvent.

### Solder Resist Layer

As described above, the solder resist layer 30 is a layer composed of an insulating resin composition. A composition of the insulating resin composition that forms the solder resist layer 30 is not particularly limited. However, typically, the solder resist layer 30 can be an insulating resin composition layer formed by photocuring a photosensitive resin composition that contains at least a photosensitive resin and a photopolymerization initiator.

Here, a photosensitive resin is also referred to as a photosensitive polymer, a photopolymer, or the like. A photosensitive resin is a polymer compound of which a physical property changes as a result of a photochemical reaction, and is typically a polymer compound that can be cured by light irradiation in the presence of a photopolymerization initiator. A representative example of a photosensitive resin is a polymer compound having a radical polymerizable double bond. A photosensitive resin, for example, is a polymer compound that contains, in a side chain, a (meth)acryloyl group derived from at least one (referred to as a “(meth)acrylic acid”) selected from an acrylic acid and a methacrylic acid. Specifically, an example of a photosensitive resin is a photosensitive resin obtained by (meth)acrylating a thermosetting group of a thermosetting resin having the thermosetting group. An example of the thermosetting resin having a thermosetting group is an epoxy resin having an epoxy group, which is a thermosetting group. Examples of the epoxy resin include a novolak type epoxy resin such as a phenol novolak type epoxy resin or an alkylphenol novolak type epoxy resin (such as a cresol novolak type epoxy resin), and an alicyclic epoxy resin, and the like. In particular, a novolac type epoxy resin is preferable. As a (meth)acrylate of an epoxy resin, in particular, a (meth)acrylate of an epoxy resin that has two or more epoxy groups remaining in one molecule and has both thermosetting and photosensitive properties is preferable. It is also possible that two or more photosensitive resins are used in combination.

A photopolymerization initiator is a compound capable of absorbing light to provide radical active species. Representative examples of photopolymerization initiators include aromatic ketones. Examples of photopolymerization initiators of aromatic ketones include alkylphenone derivatives and benzophenone derivatives. It is also possible that two or more photopolymerization initiators are used in combination.

The photosensitive resin composition may further contain other components. Examples of the other components that can be contained in the photosensitive resin composition include a photosensitizer, a thermosetting resin, an epoxy resin curing agent, an inorganic filler, and the like.

A photosensitizer can be suitably selected according to a wavelength of light to irradiated, a photopolymerization initiator, and the like. Examples of photosensitizers include Michler's ketone, thioxanthone-based photosensitizers, and the like. It is also possible that two or more photosensitizers are used in combination.

Specific examples of thermosetting resins include an epoxy resin, a phenol resin, a polyimide resin, a polyester resin, a bismaleimide resin, a polyolefin-based resin, a polyphenylene ether resin, and the like. It is also possible that two or more thermosetting resins are used in combination.

Examples of the epoxy resin include a bisphenol A type epoxy resin, a bisphenol F type epoxy resin, a novolac type epoxy resins such as a phenol novolac type epoxy resin or an alkylphenol novolac type epoxy resin (such as a cresol novolak type epoxy resin), an alicyclic epoxy resin, a biphenyl type epoxy resin, a naphthalene type epoxy resin, a dicyclopentadiene type epoxy resin, an epoxy compound of a condensate of a phenol and an aromatic aldehyde having a phenolic hydroxyl group, triglydisyl isocyanurate, and the like. It is also possible that two or more epoxy resins are used in combination.

An epoxy resin curing agent is used in combination when an epoxy resin is used as a thermosetting resin. An epoxy resin curing agent is involved in cross-link formation between epoxy groups. Examples of epoxy resin curing agents include imidazole-based curing agents, amine-based curing agents, acid anhydride-based curing agents, phenol-based curing agents, polymercaptan-based curing agents, and the like. Imidazole-based curing agents are particularly preferable. It is also possible that two or more epoxy resin curing agents are used in combination.

Examples of inorganic fillers include silica, barium sulfate, talc, and the like.

The photosensitive resin composition may be used in a form of a fluid (liquid or paste) containing a suitable solvent. The solvent is not particularly limited. However, for example, glycol ethers can be used. Examples of glycol ethers include diethylene glycol dimethyl ether, triethylene glycol dimethyl ether, and the like. It is also possible that two or more solvents are used in combination.

As the photosensitive resin composition, a separately prepared photosensitive dry film may be used.

The photosensitive resin composition may be independently prepared, or may be a commercially available composition for forming a solder resist, or may be obtained by modifying a commercially available composition for forming a solder resist.

In the present embodiment, the solder resist layer 30 is a layer formed by photocuring a photosensitive resin composition that contains a resin having an acryloyl group or a methacryloyl group or a functional group derived from an acryloyl group or a methacryloyl group, and contains a resin having an acryloyl group or a methacryloyl group or a functional group derived from an acryloyl group or a methacryloyl group. Here, “a functional group derived from an acryloyl group or a methacryloyl group” is, for example, a functional group formed as a result of mutual radical polymerization between acryloyl groups or methacryloyl groups. Specific examples of the photosensitive resin composition that contains a resin having an acryloyl group or a methacryloyl group or a functional group derived from an acryloyl group or a methacryloyl group are as described above. An acryloyl group or a methacryloyl group or a functional group derived from an acryloyl group or a methacryloyl group is a polar group. Therefore, the solder resist layer 30 that contains a resin having these groups has high affinity with the surface bonding layer 50 containing copper and nitrogen, which will be described in detail below, and thus can be firmly bonded to the surface conductor layer 26 via the surface bonding layer 50 containing copper and nitrogen.

### Internal Bonding Layer

The internal bonding layers 60 are formed for respectively bonding the first insulating layer 21 and the second insulating layer 24, which are interlayer insulating layers, to the first conductor layer 12 and the second conductor layer 23.

The internal bonding layers 60 have irregularities on surfaces in contact with the first insulating layer 21 and the second insulating layer 24, and the surfaces each have an arithmetic average roughness (Ra) or 100 nm or more and 300 nm or less. The internal bonding layers 60 having such fine uneven surfaces can be respectively firmly bonded to the first insulating layer 21 and the second insulating layer 24 due to an anchor effect.

As described above, in order for the first insulating layer 21 and the second insulating layer 24, which are interlayer insulating layers, to have low dielectric properties, it is preferable that the first insulating layer 21 and the second insulating layer 24 be each forming of a resin having few polar groups. However, it is not easy to bond an interlayer insulating layer formed of such a resin to a conductor layer, for example, by a chemical action such as in the case of the surface bonding layer 50 to be described later. The internal bonding layers 60 having fine uneven surfaces are each bonded to an interlayer insulating layer by a physical action and thus can each be bonded to the interlayer insulating layer regardless of the polarity of the resin, and thus are preferable.

In a more preferred embodiment, the first conductor layer 12 and the second conductor layer 23, on which the internal bonding layers 60 are respectively formed, are each a layer containing copper, and the internal bonding layers 60 are each a layer containing copper crystals. The first conductor layer 12 and the second conductor layer 23 more preferably each include a layer of electrolessly plated copper or electrolytically plated copper. The crystals are preferably needle-like copper crystals. The copper crystals have high affinity with copper. Therefore, the internal bonding layers 60 containing copper crystals can be respectively bonded to the first conductor layer 12 and the second conductor layer 23 with sufficient strengths.

Before the internal bonding layers 60 containing copper crystals are formed, the conductor layers (12, 23) (the first conductor layer 12 and the second conductor layer 23) containing copper preferably each have an arithmetic average roughness (Ra) of less than 100 nm as described above. By respectively forming the internal bonding layers 60 containing copper crystals on the first conductor layer 12 and the second conductor layer 23, of which the surfaces have such small Ra values, the printed wiring board (1A) in which electrical loss is suppressed can be obtained.

An example of a method for respectively forming the internal bonding layers 60 containing copper crystals on the conductor layers (12, 23) is the following method. First, a solution containing sodium chlorite is brought into contact with the surface of each of the conductor layers (12, 23) containing copper to generate needle-like copper oxide crystals. Thereafter, the copper oxide is reduced to copper using a reducing agent such as dimethylamine borane.

The internal bonding layers 60 containing copper crystals can also be formed using commercially available reagents.

### Surface Bonding Layer

A preferred embodiment of the surface bonding layer 50 is described below.

FIG. 3 illustrates a schematic view in which a region (X) in FIG. 1 is enlarged. The region (X) is a portion of the surface conductor layer 26 where the third conductor pad (26P), the solder bump (S₁), the surface bonding layer 50 and the solder resist layer 30 are close to each other.

In the present embodiment, the surface bonding layer 50 preferably has a thickness (T) of 20-200 nm. That the thickness (T) is in this range is preferable in that the surface bonding layer 50 can perform a function of allowing the surface conductor layer 26 (the third conductor pads (26P)) and the solder resist layer 30 to be firmly bonded to each other.

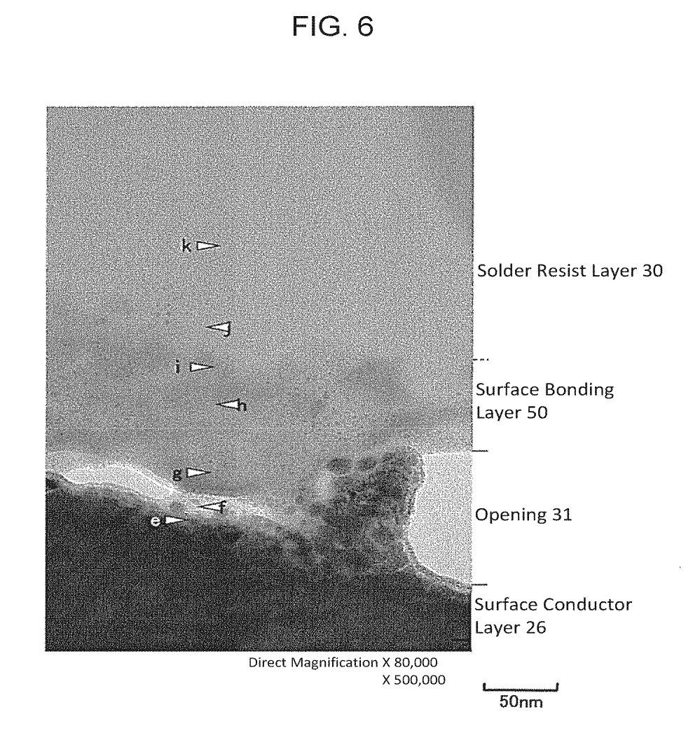

In the present embodiment, the surface conductor layer 26 is a layer containing copper, and the surface bonding layer 50 contains copper and nitrogen. FIG. 6 illustrates a picture of a TEM (transmission electron microscope) observation image of a cross section of an actually prepared printed wiring board (1A) in which the surface conductor layer 26 composed of electrolytically plated copper, the surface bonding layer 50, and the solder resist layer 30 are laminated. A void at bottom right in FIG. 6 corresponds to an opening 31 of the solder resist layer 30. A surface treatment layer containing nickel is provided in a portion of the surface conductor layer 26 facing the opening 31. A solder bump is not provided in the opening 31. In FIG. 6, a scale bar indicates 50 nm. An element composition at each point indicated in FIG. 6 was evaluated using an X-ray photoelectron spectroscopy (XPS) that analyzes an element composition by irradiating X-rays and measuring a generated photoelectron energy. The surface of the surface conductor layer 26 is indicated by a point (e).

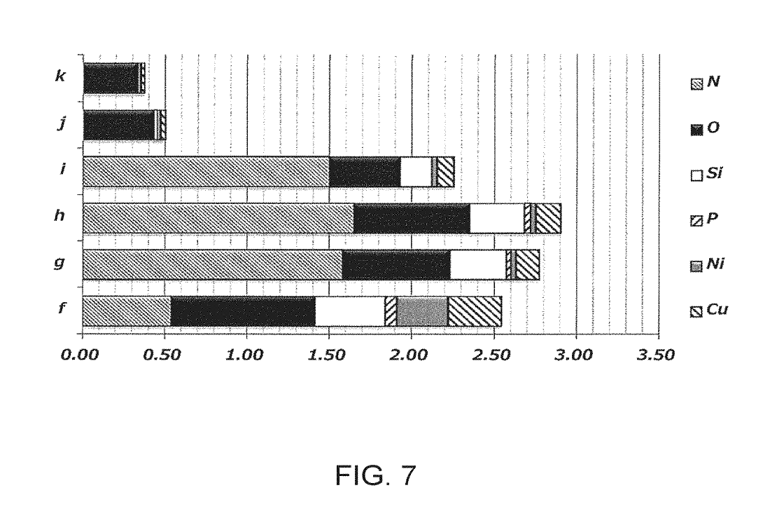

The results of XPS are illustrated in FIG. 7. Numerical values on a horizontal axis respectively indicate mass ratios of elements. In addition to the elements illustrated in FIG. 7, carbon is contained. However, a relative amount of carbon is significantly larger than the other elements and thus is not illustrated in FIG. 7. Nitrogen (N) and copper (Cu) exist at each point from a point (f) to a point (i). The point (i) is about 115 nm away from the point (e) of the surface of the surface conductor layer 26 composed of electrolytically plated copper. Nickel (Ni) contained at the point (f) possibly originates from the surface treatment layer provided in the portion of the surface conductor layer 26 facing the opening 31. A point (j) and a point (k) are respectively about 145 nm and about 210 nm away from the point (e), and nitrogen (N) and copper (Cu) are substantially not contained at these points. A portion of about 120 nm (including the points (f, g, h, i)) laminated on the surface conductor layer 26 composed of electrolytically plated copper corresponds to the surface bonding layer 50, and a portion above that portion corresponds the solder resist layer 30.

The surface bonding layer 50 is interposed as an interface between the surface conductor layer 26 (the third conductor pads (26P)) and the solder resist layer 30 and has a function of bonding the two to each other. In particular, as illustrated in FIGS. 1 and 3, in the case where the third conductor pads (26P) are SMD pads, when the surface bonding layer 50 does not exists, when the solder bumps (S₁) are respectively introduced into the openings 31, the interface between the third conductor pads (26P) (surface conductor layer 26) and the solder resist layer 30 on the third conductor pads (26P) is likely to peel off starting from the laminated base material vicinity portions (31a) of the openings 31. On the other hand, according to the present embodiment, the third conductor pads (26P), which are SMD pads, and the solder resist layer 30 on the third conductor pads (26P) are bonded to each other via the surface bonding layer 50. Therefore, the third conductor pads (26P) and the solder resist layer 30 are unlikely to peel off from each other.

The surface bonding layer 50 is preferably formed by bringing a liquid composition into contact with the surface of the surface conductor layer 26 and drying the liquid composition, the liquid composition containing an azole compound (which has two or more nitrogen atoms in one aromatic ring) and a liquid medium, and the surface conductor layer 26 containing electrolytically plated copper. The drying is preferably performed in an oxidation condition, for example, in an air atmosphere at a relatively high temperature, for example, 20-130° C., more preferably, 45-100° C. By drying in this condition, copper of the surface of the surface conductor layer 26 is oxidized into copper (II) ions and diffuses into a coating containing the azole compound. The azole compound coordinates to a copper (II) ion by an unshared electron pair on a nitrogen atom, and multiple nitrogen atoms can coordinate to one copper (II) ion. In addition, the azole compound has two or more nitrogen atoms in one ring, and the nitrogen atoms can each coordinate to a copper (II) ion. Therefore, in the coating containing the azole compound, the diffused copper (II) ions and the azole compound are alternately bonded to form a polymer. The surface bonding layer 50, which is such a coating, has affinity with both the surface conductor layer 26 containing copper and the solder resist layer 30 containing resin, and can bond the surface conductor layer 26 and the solder resist layer 30 to each other.

The azole compound having two or more nitrogen atoms in one aromatic ring may have an azole ring having two or more nitrogen atoms in one aromatic ring, and may have a substituent group on a ring. Examples of the azole compound include a diazole compound in which the azole ring part is a diazole (1,2-diazole or 1,3-diazole), a triazole compound in which the azole ring part is a triazole (1,2,3-triazole or 1,2,4-triazole), a tetrazole compound in which the azole ring part is 1H-tetrazole, and the like.

As the liquid medium used for preparing the liquid composition containing the azole compound, water or an organic solvent can be used.

As water, pure water such as ion exchanged water or distilled water can be used.

As the organic solvent, methanol, ethanol, propanol and the like can be used.

A mixture of two or more of the liquid media can also be used.

In the present embodiment, concentration of the azole compound in the liquid composition is preferably 0.001-10 mass %, and more preferably 0.01-5 mass %. When the concentration of the azole compound is in this range, a bonding effect between the surface conductor layer 26 and the solder resist layer 30 is sufficient and it is economical.

A method for bringing the liquid composition into contact with the surface of the surface conductor layer 26 is not particularly limited, and method such as immersion, coating, and spraying can be used.

A time period (treatment time) in which the liquid composition is in contact with the surface of the surface conductor layer 26 is not particularly limited, but can be 1 second-10 minutes, and more preferably 5 seconds-3 minutes. When the treatment time is in the above-described range, a coating of the liquid composition having a sufficient thickness can be easily formed on the surface of the surface conductor layer 26. When the liquid composition is in contact with the surface of the surface conductor layer 26, a temperature of the liquid composition is preferably 5-50° C., but can be appropriately set in relation to the treatment time.

After the liquid composition has been brought into contact with the surface of the surface conductor layer 26, drying may be performed after washing with water, or drying may be performed without washing with water. The drying temperature is as described above.

As the water used for the washing with water, pure water such as ion exchanged water or distilled water is preferable. However, a method and a time period for the washing with water are not particularly limited. For example, the washing may be performed using a method such as immersion or spraying for an appropriate time period.

Before the liquid composition is brought into contact with the surface conductor layer 26, the surface may be subjected to at least one pretreatment selected from a pickling treatment, a heat resistant treatment, a rust preventive treatment and a chemical conversion treatment.

The pickling treatment is performed in order to remove an oil component attached to the surface of the surface conductor layer 26 and to remove an oxide film on a surface of copper. For the pickling treatment, a solution such as a hydrochloric acid based solution, a sulfuric acid based solution, a nitric acid based solution, a sulfuric acid—hydrogen peroxide based solution, an organic acid based solution, an inorganic acid—organic solvent based solution, an organic acid—organic solvent based solution, or the like can be used.

The heat resistant treatment is a treatment in which a coating of at least one material selected from nickel, nickel-phosphorus, zinc, zinc-nickel, copper-zinc, copper-nickel, copper-nickel-cobalt and nickel-cobalt is formed on the surface of the surface conductor layer 26 containing electrolytically plated copper. The formation of the coating can be performed using an electrolytic plating method. However, the formation of the coating is not limited to using electrolytic plating. Vapor deposition or other methods may also be used.

The rust preventive treatment is performed to prevent oxidation corrosion of the surface of the surface conductor layer 26 containing electrolytically plated copper, and a method in which a plating film of zinc or a zinc alloy composition or a plating film of electrolytic chromate is formed on the surface of copper.

In the above chemical conversion treatment, a method in which a passive film of tin is formed on the surface of the surface conductor layer 26 containing electrolytically plated copper, or a method in which a passive film of copper oxide is formed, can be adopted.

Before the liquid composition is brought into contact with the surface of the surface conductor layer 26, an aqueous solution containing copper ions may be brought into contact with the surface. The aqueous solution containing copper ions has a function of making uniform the thickness of the surface bonding layer 50 formed on the surface of the surface conductor layer 26. A copper ion source is not particularly limited as long as the copper ion source is a copper salt that is soluble in water. Examples of the copper ion source include copper salts such as copper sulfate, copper nitrate, copper chloride, copper formate, and copper acetate. To solubilize a copper salt in water, ammonia, hydrochloric acid or the like may be added.

After the liquid composition is brought into contact with the surface of the surface conductor layer 26, an acidic aqueous solution or an alkaline aqueous solution may be brought into contact with the surface. Similar to the aqueous solution containing copper ions, the acidic aqueous solution or the alkaline aqueous solution has a function of making uniform the thickness of the surface bonding layer 50 formed on the surface of the surface conductor layer 26. The acidic aqueous solution or the alkaline aqueous solution is not particularly limited. Examples of the acidic aqueous solution include an aqueous solution containing a mineral acid such as a sulfuric acid, a nitric acid, or a hydrochloric acid, an aqueous solution containing an organic acid such as a formic acid, an acetic acid, a lactic acid, a glycolic acid, or an amino acid, and the like. Examples of the alkaline aqueous solution include an aqueous solution containing an alkali metal hydroxide such as a sodium hydroxide or a potassium hydroxide, and an aqueous solution containing amine such as ammonia, ethanolamine, or monopropanolamine.

### Method for Manufacturing Printed Wiring Board

An example of a method for manufacturing the wiring board (1A) of the present embodiment is described with reference to FIG. 2A-2M.

An embodiment of the method for manufacturing the printed wiring board (1A) include at least a laminated base material formation process in which the laminated base material 2 is formed by alternately laminating the conductor layers (12, 23, 26) and the interlayer insulating layers (21, 24), and a solder resist layer formation process in which the solder resist layer 30 is formed on the surface conductor layer 26 of the laminated base material 2 obtained by the laminated base material formation process.

### Laminated Base Material Formation Process

In the present embodiment, as a starting material for forming the laminated base material 2, the core layer 10 illustrated in FIG. 2A can be used. Details of the core layer 10 are as described above with reference to FIG. 1. A method for forming the core layer 10 is not particularly limited.

A method for forming the build-up layer 20 on the core layer 10 so as to form the laminated base material 2 is not particularly limited. However, an example of the method is described with reference to FIG. 2B-2J.

First, as illustrated in FIG. 2B, the internal bonding layer 60 is formed on the first conductor layer 12 of the core layer 10 such that an outer side surface of the internal bonding layer 60 has an arithmetic average roughness (Ra) of 100 nm or more and 300 nm or less. The method for forming the internal bonding layer 60 is as described above.

Next, as illustrated in FIG. 2C, the first insulating layer 21, which is an interlayer insulating layer, is laminated. The first insulating layer 21 can be formed by forming and curing a layer of an insulating resin composition on the surface of the core layer 10 on which the internal bonding layer 60 has been formed. Specific examples of the insulating resin composition for forming the first insulating layer 21 are as described above. When a thermosetting resin composition is used as the insulating resin composition, the first insulating layer 21 can be formed by performing a heat treatment to sure the layer of the insulating resin composition.

The first insulating layer 21 is illustrated as a single layer in the drawings. However, it is also possible that the first insulating layer 21 is formed by laminating multiple layers.

A thickness of the first insulating layer 21 is not particularly limited. However, for example, the thickness can be 5-100 μm.

Next, as illustrated in FIG. 2D, via holes (holes) 121 are formed in part of the first insulating layer 21 such that surfaces of the first conductor pads (12P) of the first conductor layer 12 are exposed. A method for forming the via holes 121 is not particularly limited. However, for example, the via holes 121 can be formed in the first insulating layer 21 by a treatment using CO₂ laser. In this case, it is preferable to also remove the internal bonding layer 60 in the via holes 121 to expose the surfaces of the first conductor pads (12P). The internal bonding layer 60 on the first conductor pads (12P) exposed in the via holes 121 can be removed by etching.

Next, as illustrated in FIG. 2E, the surface of the first insulating layer 21, and the surfaces of the first conductor pads (12P) exposed in the via holes 121, are covered by the second seed layer (23a) by electroless plating or sputtering.

Next, as illustrated in FIG. 2F, the first conductor vias 22 and the second electrolytic plating layer (23b) are formed. Specifically, although not illustrated in the drawings, a resist is applied on the second seed layer (23a) to form a resist layer of a predetermined pattern. Subsequently, the second electrolytic plating layer (23b) composed of copper is formed on a portion not covered by the resist layer. Removal of the resist layer, and removal of the second seed layer (23a) that is exposed by the removal of the resist layer, are performed by an etching treatment. As a result, the first conductor vias 22 can be formed in the via holes 121, and the second conductor layer 23 that includes the second seed layer (23a) and the second electrolytic plating layer (23b) can be formed on the surface of the first insulating layer 21.

Further, as illustrated in FIG. 2G, the internal bonding layer 60 is further formed on the second conductor layer 23 such that an outer side surface of the internal bonding layer 60 has an arithmetic average roughness (Ra) of 100 nm or more and 300 nm or less. The method for forming the internal bonding layer 60 is as described above.

Next, as illustrated in FIG. 2H, the second insulating layer 24, which is an interlayer insulating layer, is laminated. The via holes 124 are formed in the second insulating layer 24 such that surfaces of the second conductor pads (23P) of the second conductor layer 23 are exposed. The method forming the second insulating layer 24 is the same as the method for forming the first insulating layer 21. The method for forming the via holes 124 in the second insulating layer 24 is the same as the method for forming the via holes 121 in the first insulating layer 21.

The second insulating layer 24 is illustrated as a single layer in the drawings. However, it is also possible that the second insulating layer 24 is formed by laminating multiple layers.

A thickness of the second insulating layer 24 is not particularly limited. However, for example, the thickness can be 5-100 μm.

Next, as illustrated in FIG. 2I, the surface of the second insulating layer 24, and the surfaces of the second conductor pads (23P) exposed in the via holes 124, are covered by the third seed layer (26a) by electroless plating or sputtering.

Next, as illustrated in FIG. 2J, the second conductor vias 25 and the third electrolytic plating layer (26b) are formed. Specifically, although not illustrated in the drawings, a resist is applied on the third seed layer (26a) to form a resist layer of a predetermined pattern. Subsequently, the third electrolytic plating layer (26b) composed of copper is formed on a portion not covered by the resist layer. Removal of the resist layer, and removal of the third seed layer (26a) that is exposed by the removal of the resist layer, are performed by an etching treatment. As a result, the second conductor vias 25 can be formed in the via holes 124, and the surface conductor layer (third conductor layer) 26 that includes the third seed layer (26a) and the third electrolytic plating layer (26b) can be formed on the surface of the second insulating layer 24. The surface conductor layer 26 can be formed as a pattern that includes the surface conductor pads (third conductor pads) (26P) and the surface conductor wirings (third conductor wirings) (26L).

Here, the surface of the surface conductor layer (third conductor layer) 26 preferably has an arithmetic average roughness (Ra) of less than 100 nm immediately before the later-described solder resist layer formation process. The surface conductor layer (third conductor layer) 26 having such a surface can be formed by electrolytic plating.

By the above process, the laminated base material 2 can be formed.

### Solder Resist Layer Formation Process

Before the solder resist layer 30 is formed, as illustrated in FIG. 2K, it is preferable that the surface bonding layer 50 be formed on the surface of the surface conductor layer 26.

The method for forming the surface bonding layer 50 is as described above. Preferably, the surface bonding layer 50 is formed by bringing a liquid composition into contact with the surface of the surface conductor layer 26 and drying the liquid composition, the liquid composition containing the azole compound and a liquid medium, and the surface conductor layer 26 containing electrolytically plated copper. More specific aspects of the method for forming the surface bonding layer 50 are as described above.

Next, as illustrated in FIG. 2L, on a surface (2a) of the laminated base material 2 where the surface conductor layer 26 is formed, a solder resist precursor layer 40 composed of a resin composition, from which the solder resist layer 30 can be formed by curing, is formed.

The solder resist precursor layer 40 is illustrated as a single layer in the drawings. However, it is also possible that the solder resist precursor layer 40 is formed by laminating multiple layers.

An example of the resin composition from which the solder resist layer 30 can be formed is the above-described photosensitive resin composition that contains a photosensitive resin and a photopolymerization initiator. In this case, the resin composition is prepared as a fluid containing the above-described solvent. The fluid is applied to the laminated base material 2 to form a coating film. Subsequently, the solvent is removed from the coating film by volatilization (that is, the coating film is dried). Thereby, the solder resist precursor layer 40 can be formed. An example of another method is a method in which a solder resist precursor layer 40 composed of the resin composition prepared separately as a dry film is laminated on the laminated base material 2.

In the present embodiment, a thickness of the solder resist precursor layer 40 is not particularly limited, but is in a range of 5-50 μm.

In an embodiment in which a layer of a photosensitive resin composition that can be cured by light irradiation is used as the solder resist precursor layer 40, the following exposure process is performed. A preferred embodiment of the exposure process is a process in which the solder resist precursor layer 40 except for regions corresponding to the openings 31 (see FIG. 2M) is irradiated with light and is thereby cured. The exposure process can be typically performed by irradiating light to the solder resist precursor layer 40 in a state in which a light shielding mask that selectively shields the regions corresponding to the openings 31 is positioned on a surface of the solder resist precursor layer 40.

Conditions such as a wavelength of the light to be irradiated, light illuminance, and irradiation time in the exposure process can be suitably determined according to the resin composition that forms the solder resist precursor layer 40. The light to be irradiated is ultraviolet light.

After the exposure process, a developing process is performed. The developing process is a process in which, after the exposure process, development is performed using a liquid developer to form the solder resist layer 30 in which the openings 31 are formed (see FIG. 2M).

As the liquid developer, a solvent in which an uncured portion of the solder resist precursor layer 40 is soluble and a photocured portion of the solder resist precursor layer 40 is insoluble can be used. An example of such a solvent is the same solvent as that used in forming the above-described fluid.

When the solder resist layer 30 obtained by the developing process can be further photocured, it is preferable that, after the developing process, a photocuring completion process be performed in which light irradiation is further performed to complete the photocuring.

Further, when the solder resist layer 30 obtained by the developing process contains thermosetting resin, it is preferable that, after the developing process, a thermal curing process be performed in which the solder resist layer 30 is thermally cured.

### Solder Bump Formation Process

Further, a solder bump formation process is performed in which the solder bumps (S₁) are respectively provided on the third conductor pads (26P) in the openings 31. In the present embodiment, further, it is preferable that, before the solder bumps (S₁) are provided, portions of the surface bonding layer 50 exposed in the openings 31 be removed by etching. In the present embodiment, further, it is preferable that the solder bump formation process be performed after a surface treatment layer (not illustrated in the drawings) for preventing oxidation is provided on each of the surfaces of the third conductor pads (26P) that are exposed by removing the portions of the surface bonding layer 50. Specific examples of the surface treatment layer are as described above.

### Printed Wiring Board

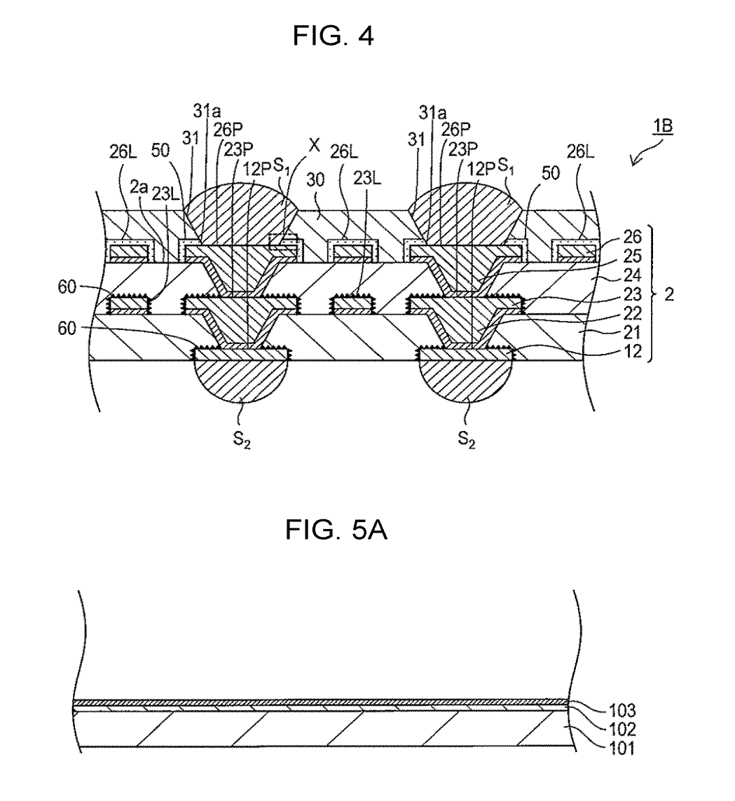

A printed wiring board (1B) according to another embodiment of the present invention is structured as illustrated in the schematic cross-sectional view of FIG. 4.

The printed wiring board (1B) illustrated in FIG. 4 is an example of a coreless printed wiring board that does not include the core layer 10.

The printed wiring board (1B) illustrated in FIG. 4 includes at least a laminated base material 2 that is formed by alternately laminating a first conductor layer 12, a first insulating layer 21, a second conductor layer 23, a second insulating layer 24, and a surface conductor layer (third conductor layer) 26, and a solder resist layer 30 that is laminated on a surface (2a) of the laminated base material 2 where the surface conductor layer 26 is formed. Solder bumps (S₁) are respectively provided on third conductor pads (26P) in openings 31. Further, solder bumps (S₂) are provided on an outer side surface of the first conductor layer 12. First conductor vias 22 that penetrate the first insulating layer 21 and electrically connect the first conductor layer 12 and the second conductor layer 23 are formed in the first insulating layer 21. Second conductor vias 25 that penetrate the second insulating layer 24 and electrically connect the second conductor layer 23 and the surface conductor layer 26 are formed in the second insulating layer 24.

Components indicated by reference numeral symbols in the printed wiring board (1B) have the same characteristics as those indicated by the same reference numeral symbols in the printed wiring board (1A), and thus description of the component is omitted.

In the coreless printed wiring board (1B), the first conductor layer 12 does not form a part of the core layer 10 as illustrated in FIG. 1, but is positioned as an outermost layer of the laminated base material 2. The first conductor layer 12 can be formed of electrolytically plated copper.

A method for manufacturing the coreless printed wiring board (1B) is not particularly limited. A method for manufacturing a coreless printed wiring board and the above-described method for manufacturing the printed wiring board (1A) may be used in combination.

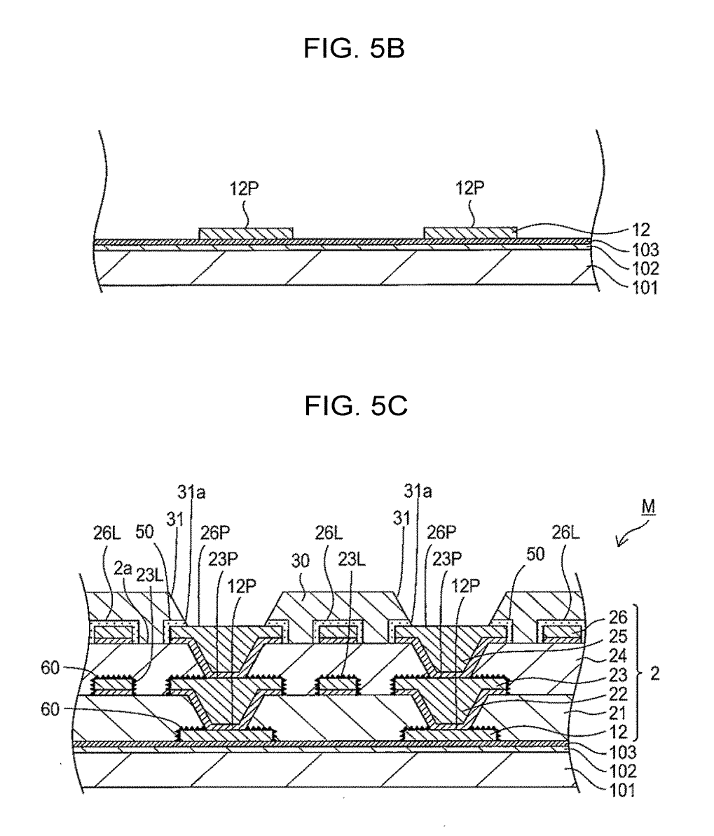

An example of the method for manufacturing the coreless printed wiring board (1B) is described with reference to FIG. 5A-5C.

First, as illustrated in FIG. 5A, a carrier 101, on which a copper foil 103 is laminated via a bonding layer 102, is prepared. The bonding layer 102 bonds the carrier 101 and the copper foil 103 in a state in which the copper foil 103 can be peeled off from the carrier 101.

Next, a resist layer (not illustrated in the drawings) of a predetermined pattern is formed on the copper foil 103. By an electrolytic plating treatment, the first conductor layer 12, which is a pattern that includes first conductor pads (12P), is formed on a surface of the copper foil 103 where the resist layer is not formed. The resist layer is removed (see FIG. 5B).

Thereafter, on the surface of the copper foil 101 including the first conductor layer 12, by the same procedures as described with reference to FIG. 2A-2M regarding the printed wiring board (1A), the laminated base material 2, the surface bonding layer 50 and the solder resist layer 30 are formed, and an intermediate product (M) as illustrated in FIG. 5C is obtained.

Thereafter, the carrier 101 and the bonding layer 102 are removed from the intermediate product (M) illustrated in FIG. 5C, and further, the copper foil 103 is removed by etching. Finally, the solder bumps (S₁) are respectively provided on the third conductor pads (26P) in the openings 31 of the solder resist layer 30, the solder bumps (S₂) are provided on the surface of the first conductor layer 12, and the coreless printed wiring board (1B) illustrated in FIG. 4 can be obtained.

In a printed wiring board, in order to increase adhesion between a surface conductor layer and a solder resist layer, a surface of the surface conductor layer may be treated. For example, Japanese Patent Laid-Open Publication No. HEI 10-150250 describes that, in a printed wiring board in which a solder resist layer is provided on a surface of a wiring substrate in which a conductor circuit is formed, a surface of the conductor circuit is formed as a roughened layer. Japanese Patent Laid-Open Publication No. HEI 10-150250 describes that, as the roughened layer, a roughened surface of copper formed by subjecting the surface of the conductor circuit to an etching treatment, a polishing treatment, an oxidation treatment, or an oxidation reduction treatment, or a roughened surface of a coating formed by subjecting the surface of the conductor circuit to a plating treatment, is desirable.

In a printed wiring board having a conductor layer that contains electrolytically plated copper and an interlayer insulating layer and solder resist layer that are in contact with the conductor layer, there is a difference in thermal expansion coefficient between the conductor layer and the interlayer insulating layer and the solder resist layer. Therefore, when the printed wiring board is exposed to thermal variations, delamination (haloing) may occur between the conductor layer and the interlayer insulating layer or the solder resist layer. When haloing occurs, a short circuit may occur between adjacent portions of the conductor layer.

On the other hand, when a current in a high frequency region flows through the conductor layer, a skin effect occurs in which the current flows only in a region near a surface of the conductor layer. However, when the surface of the conductor layer is roughened as in Japanese Patent Laid-Open Publication No. HEI 10-150250, when the skin effect occurs, resistance increases and electrical loss occurs.

A printed wiring board according to an embodiment of the present invention includes: a laminated base material that includes two or more conductor layers and an interlayer insulating layer that is an insulating layer formed between the conductor layers; and a solder resist layer that is an insulating layer laminated on at least one of surfaces of the laminated base material.

The laminated base material includes, as at least a part of the conductor layers, a surface conductor layer on a surface where the solder resist layer is laminated.

An internal bonding layer is interposed at least partially between the interlayer insulating layer and at least one of a pair of conductor layers sandwiching the interlayer insulating layer.

A surface of the internal bonding layer in contact with the interlayer insulating layer has an arithmetic average roughness (Ra) of 100 nm or more and 300 nm or less.

A surface of the surface conductor layer on the solder resist layer side has an arithmetic average roughness (Ra) of less than 100 nm.

A method for manufacturing a printed wiring board according to an embodiment of the present invention includes: a laminated base material that includes two or more conductor layers and an interlayer insulating layer that is an insulating layer formed between the conductor layers; and a solder resist layer that is an insulating layer laminated on at least one of surfaces of the laminated base material.

The laminated base material includes, as at least a part of the conductor layers, a surface conductor layer on a surface where the solder resist layer is laminated.

The method includes: a laminated base material formation process in which the laminated base material is formed by alternately laminating the conductor layers and the interlayer insulating layer; and a solder resist layer formation process in which the solder resist layer is formed on the surface conductor layer of the laminated base material obtained by the laminated base material formation process.

The laminated base material formation process includes: an internal bonding layer formation process in which an internal bonding layer is formed on a conductor layer having a surface that has an arithmetic average roughness (Ra) of less than 100 nm such that an outer surface of the internal bonding layer has an arithmetic average roughness (Ra) of 100 nm or more and 300 nm or less; an interlayer insulating layer formation process in which an interlayer insulating layer is formed on the conductor layer on which the internal bonding layer has been formed; and a conductor layer formation process in which a conductor layer is further formed on the interlayer insulating layer.

In the solder resist layer formation process, a surface of the surface conductor layer has an arithmetic average roughness (Ra) of less than 100 nm.

In a printed wiring board according to an embodiment of the present invention, the conductor layer and the interlayer insulating layer, and the conductor layer and the solder resist layer, can be respectively in close contact with each other, and delamination (haloing) between the respective layers can be suppressed.

Obviously, numerous modifications and variations of the present invention are possible in light of the above teachings. It is therefore to be understood that within the scope of the appended claims, the invention may be practiced otherwise than as specifically described herein.

1. A printed wiring board, comprising:
a laminated base material comprising a surface conductor layer, a conductor layer, an interlayer insulating layer interposed between the surface conductor layer and the conductor layer, and an internal bonding layer interposed between the interlayer insulating layer and at least one of the surface conductor layer and the conductor layer; and
a solder resist layer laminated on a surface of the laminated base material such that the solder resist layer is covering the surface conductor layer,
wherein the internal bonding layer has a surface in contact with the interlayer insulating layer such that the surface of the internal bonding layer has an arithmetic average roughness Ra in a range of 100 nm or more and 300 nm or less, and the surface conductor layer has a surface on a solder resist layer side such that the surface of the surface conductor layer has an arithmetic average roughness Ra of less than 100 nm.

2. A printed wiring board according to claim 1, wherein the conductor layer comprises copper, the surface conductor layer comprises copper, and the internal bonding layer comprises copper crystals.

3. A printed wiring board according to claim 1, further comprising:
a surface bonding layer interposed between the surface conductor layer and the solder resist layer,
wherein the conductor layer comprises copper, the surface conductor layer comprises copper, and the surface bonding layer comprises a layer comprising copper and nitrogen and having a thickness in a range of 20 nm to 200 nm.

4. A printed wiring board according to claim 1, wherein the interlayer insulating layer is a resin layer comprising a resin that does not have an acryloyl group, a methacryloyl group, a functional group derived from an acryloyl group, and a functional group derived from a methacryloyl group, and the solder resist layer is a resin layer comprising a resin that has at least one of an acryloyl group, a methacryloyl group, a functional group derived from an acryloyl group, and a functional group derived from a methacryloyl group.

5. A printed wiring board according to claim 2, further comprising:
a surface bonding layer interposed between the surface conductor layer and the solder resist layer,
wherein the conductor layer comprises copper, the surface conductor layer comprises copper, and the surface bonding layer comprises a layer comprising copper and nitrogen and having a thickness in a range of 20 nm to 200 nm.

6. A printed wiring board according to claim 2, wherein the interlayer insulating layer is a resin layer comprising a resin that does not have an acryloyl group, a methacryloyl group, a functional group derived from an acryloyl group, and a functional group derived from a methacryloyl group, and the solder resist layer is a resin layer comprising a resin that has at least one of an acryloyl group, a methacryloyl group, a functional group derived from an acryloyl group, and a functional group derived from a methacryloyl group.

7. A printed wiring board according to claim 3, wherein the interlayer insulating layer is a resin layer comprising a resin that does not have an acryloyl group, a methacryloyl group, a functional group derived from an acryloyl group, and a functional group derived from a methacryloyl group, and the solder resist layer is a resin layer comprising a resin that has at least one of an acryloyl group, a methacryloyl group, a functional group derived from an acryloyl group, and a functional group derived from a methacryloyl group.

8. A printed wiring board according to claim 5, wherein the interlayer insulating layer is a resin layer comprising a resin that does not have an acryloyl group, a methacryloyl group, a functional group derived from an acryloyl group, and a functional group derived from a methacryloyl group, and the solder resist layer is a resin layer comprising a resin that has at least one of an acryloyl group, a methacryloyl group, a functional group derived from an acryloyl group, and a functional group derived from a methacryloyl group.

9. A printed wiring board according to claim 1, wherein the laminated base material comprises the internal bonding layer interposed between the interlayer insulating layer and one of the surface conductor layer and the conductor layer.

10. A printed wiring board according to claim 9, wherein the conductor layer comprises copper, the surface conductor layer comprises copper, and the internal bonding layer comprises copper crystals.

11. A printed wiring board according to claim 1, wherein the laminated base material comprises the internal bonding layer in a plurality such that the plurality of internal bonding layers is interposed between the interlayer insulating layer and the surface conductor layer and between the interlayer insulating layer and the conductor layer, respectively.

12. A printed wiring board according to claim 11, wherein the conductor layer comprises copper, the surface conductor layer comprises copper, and the internal bonding layer comprises copper crystals.

13. A method for manufacturing a printed wiring board, comprising:
forming a laminated base material comprising a surface conductor layer, a conductor layer, an interlayer insulating layer interposed between the surface conductor layer and the conductor layer, and an internal bonding layer interposed between the interlayer insulating layer and at least one of the surface conductor layer and the conductor layer; and
laminating a solder resist layer on a surface of the laminated base material such that the solder resist layer covers the surface conductor layer,
wherein the forming of the laminated base material comprises forming the internal bonding layer on a surface of the conductor layer having an arithmetic average roughness Ra of less than 100 nm such that the internal bonding layer has an outer surface having an arithmetic average roughness Ra in a range of 100 nm or more and 300 nm or less, and forming the interlayer insulating layer on the conductor layer on which the internal bonding layer is formed, and forming the surface conductor layer on the interlayer insulating layer, and the laminating of the solder resist layer comprises laminating the solder resist layer on a surface of the surface conductor layer having an arithmetic average roughness Ra of less than 100 nm.

14. A method for manufacturing a printed wiring board according to claim 13, wherein the conductor layer comprises copper, the surface conductor layer comprises copper, and the internal bonding layer comprises copper crystals.

15. A method for manufacturing a printed wiring board according to claim 13, further comprising:
forming a surface bonding layer on the surface conductor layer such that the surface bonding layer is interposed between the surface conductor layer and the solder resist layer,
wherein the conductor layer comprises copper, the surface conductor layer comprises copper, and the surface bonding layer comprises a layer comprising copper and nitrogen and having a thickness in a range of 20 nm to 200 nm.

16. A method for manufacturing a printed wiring board according to claim 13, wherein the interlayer insulating layer is a resin layer comprising a resin that does not have an acryloyl group, a methacryloyl group, a functional group derived from an acryloyl group, and a functional group derived from a methacryloyl group, and the solder resist layer is a resin layer comprising a resin that has at least one of an acryloyl group, a methacryloyl group, a functional group derived from an acryloyl group, and a functional group derived from a methacryloyl group.

17. A method for manufacturing a printed wiring board according to claim 14, further comprising:
a surface bonding layer interposed between the surface conductor layer and the solder resist layer,
wherein the conductor layer comprises copper, the surface conductor layer comprises copper, and the surface bonding layer comprises a layer comprising copper and nitrogen and having a thickness in a range of 20 nm to 200 nm.

18. A method for manufacturing a printed wiring board according to claim 14, wherein the interlayer insulating layer is a resin layer comprising a resin that does not have an acryloyl group, a methacryloyl group, a functional group derived from an acryloyl group, and a functional group derived from a methacryloyl group, and the solder resist layer is a resin layer comprising a resin that has at least one of an acryloyl group, a methacryloyl group, a functional group derived from an acryloyl group, and a functional group derived from a methacryloyl group.

19. A method for manufacturing a printed wiring board according to claim 15, wherein the interlayer insulating layer is a resin layer comprising a resin that does not have an acryloyl group, a methacryloyl group, a functional group derived from an acryloyl group, and a functional group derived from a methacryloyl group, and the solder resist layer is a resin layer comprising a resin that has at least one of an acryloyl group, a methacryloyl group, a functional group derived from an acryloyl group, and a functional group derived from a methacryloyl group.

20. A method for manufacturing a printed wiring board according to claim 17, wherein the interlayer insulating layer is a resin layer comprising a resin that does not have an acryloyl group, a methacryloyl group, a functional group derived from an acryloyl group, and a functional group derived from a methacryloyl group, and the solder resist layer is a resin layer comprising a resin that has at least one of an acryloyl group, a methacryloyl group, a functional group derived from an acryloyl group, and a functional group derived from a methacryloyl group.
